(19) United States
(12) Patent Application Publication
(10) Pub. No.: US 2008/0122896 A1
(43) Pub. Date: May 29, 2008

(54) INKJET PRINTHEAD WITH BACKSIDE POWER RETURN CONDUCTOR

(76) Inventor: Stanley W. Stephenson III, Spencerport, NY (US)

Correspondence Address: David A. Novais;Patent Legal Staff, Eastman Kodak Company, 343 State Street, Rochester, NY, 14650-2201, US

(21) Appl. No.: 11/556,212

(22) Filed: Nov. 3, 2006

(51) Int. Cl. B41J 2/14; H01L 21/00

(52) U.S. Cl. 347/50; 438/21; 257/E21.001

(57) ABSTRACT

A print head includes a substrate and an ejector. The substrate includes a first side and a second side. The ejector is located on the first side of the substrate and includes a fluid chamber with portions of the fluid chamber defining a nozzle bore, and a resistive element operable to eject fluid present in the fluid chamber through the nozzle bore of the fluid chamber. The resistive element is electrically connected to the substrate. A conductor is located on the second side of the substrate and is electrically connected to the substrate. A supply passage is located through the conductor and the substrate and is in fluid communication with the fluid chamber of the ejector to supply a fluid to the fluid chamber.

### CROSS REFERENCE TO RELATED APPLICATIONS

Reference is made to commonly-assigned, U.S. patent application Ser. No. 11/538,827, filed Oct. 5, 2006, entitled “ARRAY PRINTHEAD WITH THREE TERMINAL SWITCHING ELEMENTS” in the name of Stanley W. Stephenson, the disclosure of which is incorporated herein by reference.

### FIELD OF THE INVENTION

This invention relates generally to the field of digitally controlled printing devices, and in particular to print heads having significant power requirements.

### BACKGROUND OF THE INVENTION

Inkjet printing systems apply ink to a substrate. The inks are typically dyes and/or pigments in a fluid. The ink-receiving substrate can be comprised of a material or object. Most typically, the substrate is a flexible sheet that can be a paper, polymer or a composite of either type of material. The surface of the substrate and the ink are formulated to optimize the ink lay down.

Ink drops can be applied to the substrate by modulated deflection of a stream of ink (continuous) or by selective ejection from a drop generator (drop-on-demand). The drop-on-demand (DOD) systems eject ink using either a thermal pulse delivered by a resistor or a mechanical deflection of a cavity wall by a piezoelectric actuator. Ejection of the droplet is synchronized to motion of the substrate by a controller, which electrical signals to each ejector with appropriate timing to form an image.

U.S. Pat. No. 6,491,385 describes a continuous ink jet head and it's operation. A linear array of ejectors is disposed on a substrate. Each nozzle has a unique supply bore through the substrate. The supply bore ejects fluid through a nozzle in a membrane across the front surface of the supply bore. The membrane supports layers that form a pair of semi-circular resistive elements around each nozzle. Each resistor pair is pulsed to break the stream of fluid into discrete droplets. Asymmetric heating of the resistors can selectively direct the droplets into different pathways. A gutter can be used to filter out select droplets, providing a stream of selected droplets useful for printing. The modulated stream printing system requires significant additional apparatus to manage fluid flow.

Piezoelectric actuated heads use an electrically flexed membrane to pressurize a fluid-containing cavity. The membranes can be oriented in parallel or perpendicular to the ejection direction. U.S. Pat. No. 6,969,158 describes a piezoelectric drop-on-demand inkjet head having an electrically responsive piezo membrane that forces fluids through a nozzle. The inkjet head is formed of a stack of plates, which includes the piezoelectric membrane. The membranes require a large amount of surface area, and multiple rows of ejectors are arrayed in depth across the head. Ejectors are arranged across the printing direction at a pitch of 50 dpi and are arrayed in the printing direction 12 ejectors deep on an angle theta to form a head having an effective pitch of 600 dpi. Such heads are complex, requiring multiple substrates that must be bonded together to form passages to the nozzle. The materials comprising the head and the structures do not lend themselves to incorporating semiconductor-switching elements.

U.S. Pat. No. 6,926,284 discloses a drop-on-demand piezoelectric inkjet head permitting single-pass printing. A single pass print head comprises 12 linear array module assemblies that are attached to a common manifold/orifice plate assembly. Droplets are ejected from the orifice by twelve staggered linear array assemblies that support piezoelectric body assemblies to provide drop-on-demand ejection of ink through the orifice array. The piezoelectric system cannot pitch nozzles closely together; in the example, each swath module has a pitch of 50 dpi. The twelve array assemblies are necessary to provide 600 dpi resolution in a horizontally and vertically staggered fashion.

The orifice array on the plate can be a single two-dimensional array of orifices or a combination of orifices to form an array of nozzles. In the printing application, the orifices must be positioned such that the distance between orifices in adjacent lines is at last an order of magnitude (more than ten times) the pitch between print lines. The assembly is quite complex, requiring many separate array assemblies to be attached to the orifice plate thorough the use of sub frames, stiffeners, clamp bar, washers and screws. It would be advantageous to provide a staggered array in a unitary assembly with an integral orifice plate. It would be useful for the spacing between nozzles to be less than an order of magnitude deeper than is disclosed in this patent.

U.S. Pat. No. 6,722,759 describes a common thermal drop-on-demand inkjet head structure. The drop generator consists of ink chamber, an inlet to the ink chamber, a nozzle to direct the drop out of the cavity and a resistive element for creating an ink ejecting bubble. Linear arrays of drop generators are positioned on either side of an ink feed slot. Two linear arrays are fed by a common ink feed slot. Ink from the slot passes through a flow restricting ink channels to the ink chamber. A heater resistor at the bottom of the ink chamber is energized to form a bubble in the chamber and eject a drop of ink through a nozzle in the top of the chamber. A transistor is formed adjacent for each resistor to provide a three-terminal switching device to each resistor. Sets of traces are provided adjacent to the transistors to provide power, power return and switching logic to each transistor. The structure limits nozzles to be placed in linear rows on either side of the inkjet supply slot. The patent uses both power supply and return lines, increasing the complexity of the device.

U.S. Pat. No. 5,134,425 discloses a passive two-dimensional array of heater resistors. The structure and arrangement of the droplet generators is not disclosed. The patent discloses the problem of power cross talk between resistors in two-dimensional arrays of heater resistors. Voltages firing a resistor also apply partial voltages across unfired resistors. The parasitic power loss increases as the number of rows is increased to a maximum of 5 rows. The patent applies partial voltages on certain lines to reduce the voltage cross talk. The partial energy does not eject a droplet, but maintains a common elevated temperature for both fired and unfired nozzles. Passive matrix arrays of resistors are limited in the depth of the array because of the parasitic resistance. The patent suggests that the number of rows is limited to less than five rows for passive matrix thermal print heads.

U.S. Pat. No. 6,921,156 discloses forming inkjet heads on non-silicon flat-panel substrates. Thin film transistors are coupled to an array of inkjet drop generators. The monolithic substrate is described as being made of any suitable material (preferably having a low coefficient of expansion) and discloses a preferred embodiment of being ceramic. The device is multiplexed driven using flip chip devices bonded to conductors using solder. A single ink feed channel supplies two rows of nozzles. The resistors and chambers are formed using thin film processes. Multiple feedholes can supply each ejector from a single, common manifold for the two rows of ejectors. Reference to the thin film transistors on the substrate is limited, describing them as driving the resistors. The thin-film devices are formed over barrier and/or smoothing layers to isolate the thin-film devices from the substrate.

U.S. Pat. No. 6,724,078 discloses forming a metal layer over a silicon die, applying a metal layer to a lid, applying solder material to one layer and reflowing the solder when the parts are brought together to create a thermally conductive bond. U.S. Pat. No. 6,833,289 discloses applying the backside metallization process to a thinned silicon substrate and bonding the die using flux less solder to a heat spreader. A clip presses the two parts together during a reflow solder operation. U.S. Pat. No. 6,979,909 discloses a power semiconductor element that is bonded to part of a lead frame with solder. None of the metal layers are patterned for use in semiconductor devices which control fluid depositions to a substrate.

It would be useful to have a structure for an inkjet head that would use a minimum number of conductors to provide power to the ejectors. It would be useful to use the substrate to conduct power through the substrate to drive the ejectors. In the case that the substrate has insufficient power carrying capability, it would be useful to improve the conduction path through the substrate. This is particularly true of large array inkjet heads having large distances between ejectors and end of the power conduction path. It would be useful for the metal conduction layer to cover the majority of the rear surface.

### SUMMARY OF THE INVENTION

It is an object of this invention to improve conduction of power in inkjet heads that carry power through a substrate. It is an object of the invention to have a structure for an inkjet head that uses a minimum number of conductors to provide power to the ejectors. It is an object of the invention to use the substrate to conduct power through the substrate to drive the ejectors. It is an object of the invention conduction path through the substrate. It is an object of the invention to improve the power conduction path in large array inkjet heads having large distances between ejectors and end of the power conduction path. It is an object of the invention to provide a metal conduction layer that covers the majority of the rear surface. It is an object of the invention to provide a minimum number of processing steps in forming the conductor layer.

According to one feature of the invention, a print head includes a substrate and an ejector. A print head includes a substrate and an ejector. The substrate includes a first side and a second side. The ejector is located on the first side of the substrate and includes a fluid chamber with portions of the fluid chamber defining a nozzle bore, and a resistive element operable to eject fluid present in the fluid chamber through the nozzle bore of the fluid chamber. The resistive element is electrically connected to the substrate. A conductor is located on the second side of the substrate and is electrically connected to the substrate. A supply passage is located through the conductor and the substrate and is in fluid communication with the fluid chamber of the ejector to supply a fluid to the fluid chamber.

According to another feature of the invention, a method of forming a print head includes providing a substrate including a first side and a second side; providing an ejector located on the first side of the substrate, the ejector including a fluid chamber, portions of the fluid chamber defining a nozzle bore, and a resistive element operable to eject fluid present in the fluid chamber through the nozzle bore of the fluid chamber, the resistive element being electrically connected to the substrate; providing a conductor located on the second side of the substrate, the conductor being electrically connected to the substrate; providing a mask over the conductor; and forming a supply passage through the conductor and the substrate by: removing a portion of the conductor not covered by the mask; and removing a portion of the substrate not covered by the mask.

### BRIEF DESCRIPTION OF THE DRAWINGS

In the detailed description of the example embodiments of the invention presented below, reference is made to the accompanying drawings, in which:

FIG. 1 is a top schematic view of an ejector in accordance with the present invention;

FIG. 2 is a side sectional view through the ejector shown in FIG. 1;

FIG. 3 is a top view of an array of ink ejectors according to prior art;

FIG. 4 is a top view of an inkjet print head assembly in accordance with prior art;

FIG. 5 is a top view of an ejector in accordance with the present invention;

FIG. 6 is a side sectional view of a transistor on a substrate in accordance with the invention;

FIG. 7a is a side section view of an ejector on an inkjet head at a first step in the manufacturing process;

FIG. 7b is a side section view of an ejector on an inkjet head at a second step in the manufacturing process;

FIG. 7c is a side section view of an ejector on an inkjet head at a third step in the manufacturing process;

FIG. 7d is a side section view of an ejector on an inkjet head at a fourth step in the manufacturing process;

FIG. 8 is a schematic representation of an ejector array in accordance one example embodiment of the invention;

FIG. 9 is a side sectional view of an inkjet head in accordance with the invention;

FIG. 10 is an electrical schematic of an inkjet head in accordance with the present invention;

FIG. 11 is a schematic view of a head assembly in accordance with the present invention; and

FIG. 12 is a side view of a printer using a head in accordance with the present invention.

### DETAILED DESCRIPTION OF THE INVENTION

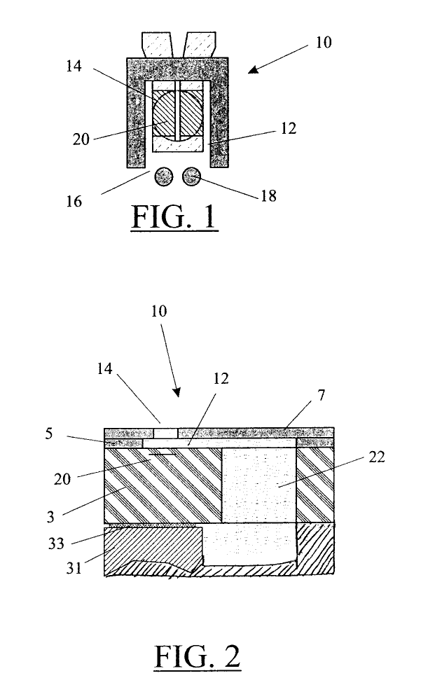

FIG. 1 is a top schematic view of an ejector 10 in accordance with the present invention. FIG. 2 is a side sectional view through the ejector shown in FIG. 1. A substrate 3 supports a polymer layer 5. Substrate 3 is most commonly a silicon wafer. In the invention, if substrate 3 is not silicon, the material can be a moderately electrically conductive ceramic, polymer or metal. An ink chamber 12 is formed as a cavity in polymer layer 5 to hold a printing ink. A cover 7 over ink chamber 12 can be formed directly over polymer layer 5 using deposited ceramic, polymer or metal. Cover 7 over ink chamber 12 can also be a separate plate formed of ceramic, polymer or metal which is bonded to the polymer layer 5 defining ink chamber 12. Cover 7 has an opening to form a nozzle 14 to direct an ejected droplet of ink in a specified direction when ink chamber 12 is pressurized.

A heater resistor 20 is embedded in the substrate 3. A pulse of electrical energy to heater resistor 20 causes ink within ink chamber 12 to momentarily be converted into a gaseous state. A gas bubble is formed over heater resistor 20 within ink chamber 12, and pressurizes ink chamber 12. Pressure within ink chamber 12 acts on ink within ink chamber 12 and forces a droplet of ink to be ejected through nozzle 14. Inlet 16 supplies ink to ink chamber 12. Restriction 18 can be formed at inlet 16 to improve firing efficiency by restricting the majority of the pressure pulse to ink chamber 12. Restrictions 18 can be in the form of one or more pillars formed within inlet 16, or by a narrowing of the sidewalls in polymer layer 5 at inlet 16 of ink chamber 12.

Resistive inkjet heads are commonly made using silicon for substrate 3. Heater resistor 20 and associated layers are formed over substrate 3, followed by polymer layer 5. Polymer layer 5 is patterned, followed by cover 7, which is patterned to form nozzle 14. After those layers have been formed, ink feed slot 22 is formed through substrate 3 using a reactive ion milling process. The reactive ion milling process has the characteristic of forming near-vertical walls through a silicon substrate 3. The ion milling process has the virtue that the process is specific to silicon and can form ink feed slot 22 without damage to structures associated with ejectors 10 on substrate 3. Substrate 3 is bonded to head holder 31, which has one or more cavities for supplying ink to some, or all of ejectors 10 formed on substrate 3. In the invention, electrical current used to power resistors 20 is returned through substrate 3. Conductive adhesive 33 should have low electrical resistance, less than 0.1 ohms resistance, to current flow between head holder 31 and substrate 3. Each ejector 10 is fed by a cavity in head holder 31 through its ink feed slot 22 in substrate 3. Each ink feed slot 22 is associated with an individual ejector 10 and is physically separated from other ejectors 10 by the material forming substrate 3.

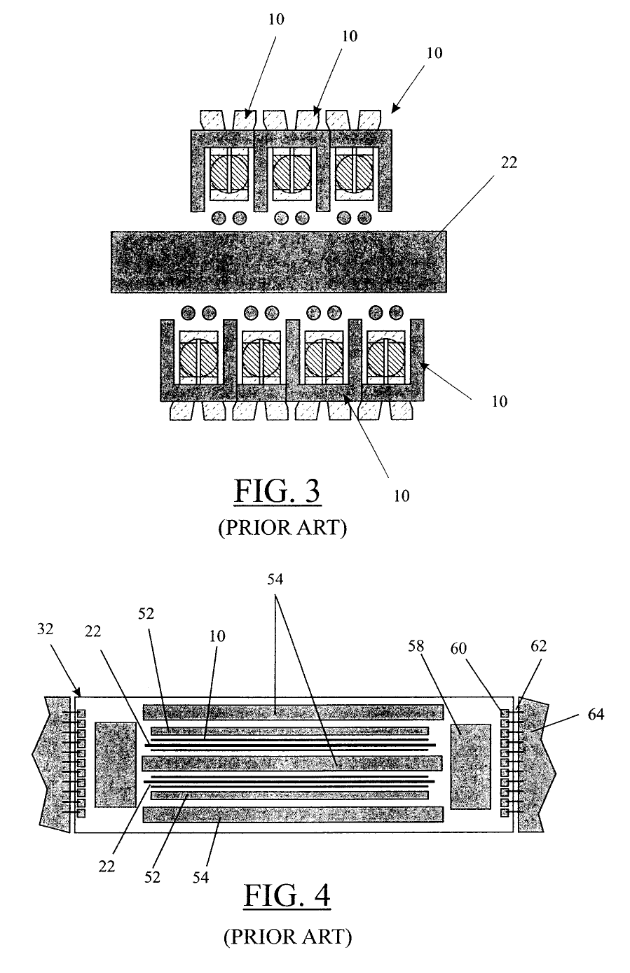

FIG. 3 is a top view of an array of prior art ink ejectors, see, for example, U.S. Pat. No. 6,722,759. Ejectors 10 are supplied with ink from the rear side of substrate 3. Ejectors 10 are arranged in two closely packed rows that share common ink feed slot 22. Ink feed slot 22 passes through substrate 3, which supplies to ink to multiple ejectors 10. Arranging two linear rows of ejectors 10 on either side of ink feed slot 22 provides for a compact inkjet head. Because the nozzles are adjacent to each other, fluidic cross-talk can occur between ejectors 10. Close packing of the nozzles makes the head susceptible to thermal cross talk between adjacent nozzles. Overheating can become more pronounced if substrate 3 is not silicon, but a less thermally conductive material such as glass, ceramic, polymer or metal.

FIG. 4 is a top view of another prior art inkjet print head, see, for example, U.S. Pat. No. 6,722,759. A print head 32 has two ink feed slots 22, each feed slot feeding two rows of ejectors 10. A set of ejector drivers 52 is formed adjacent to each row of ejectors 10. Each ejector driver 52 is a semiconductor-switching element that is attached to each heater resistor 20 within each ejector 10. The power requirements for thermal drop on demand inkjet are high, typically over 1 watt of power for approximately 1 microsecond. Ejector drivers 52 are typically formed of PMOS or NMOS transistors that are activated to selectively apply power to heater resistors 20. Alternatively, ejector drivers 52 can be formed of thin-film-transistor elements having characteristics capable of meeting the power and switching times required to thermally eject a droplet from an ejector 10.

Power to ejector drivers 52 is provided by conductor lines 54 disposed on the sides and down the center of substrate 3. Conductor lines 54 supply power and data for ejector drivers 52. Control logic 58 is disposed on both ends of substrate 3 to decode data signals from printer controller 38 (not shown). Data and power are delivered to control logic 58 through bond pads 60. Wire bonds 62 provide connection between bond pads 60 on substrate 3 and flex circuit 64. Data from control logic 58 is delivered through flex circuit 64 through wire bonds 62 to control logic 58. Control logic 58 responds to control data from printer controller 38 (not shown).

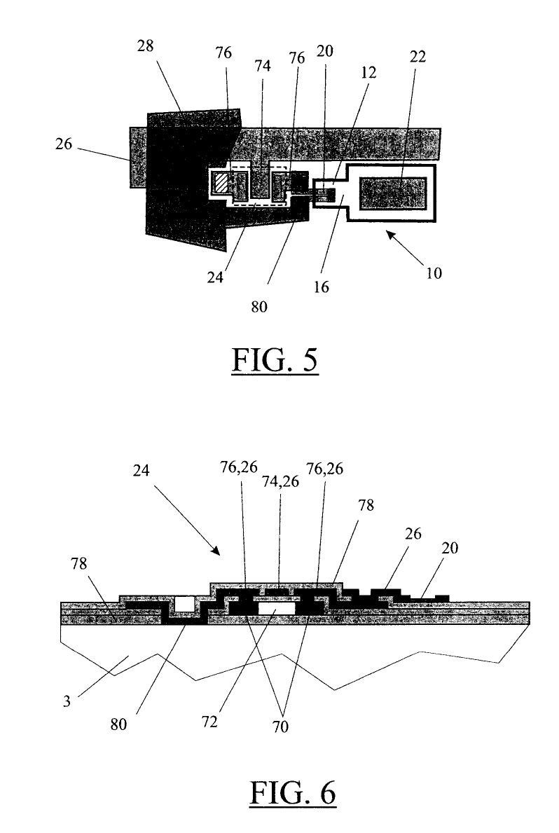

FIG. 5 is a top schematic view of an ejector in accordance with the present invention. In the invention, an ejector 10 comprises an ink chamber 12 actuated by heater resistor 20. Ink chamber 12 is fed by inlet 16 and ejects fluid through nozzle 14 (not shown) over resistor 20. Dedicated ink feed slot 22 is integral with ejector 10. In the case that substrate 3 is made of silicon, a reactive ion etching process creates a substantially columnar ink feed slot 22 through substrate 3. Ink feed slot 22 is fed from a common cavity in head holder 31 facing the back of substrate 3. Ejector 10 in accordance with the invention provides a complete assembly that can be positioned at any distance from adjacent ejectors 10 to eliminate fluidic cross talk and improve cooling efficiency. In the case that substrate 3 is not silicon, the greater distance prevents overheating that would result from closely spaced ejectors 10 on lower conductivity substrates 3.

U.S. Pat. No. 5,134,425 discloses a passive two-dimensional array of heater resistors. The patent discloses the problem of power cross talk between resistors in a passive two-dimensional array of heater resistors. A voltage applied to one resistor applies partial voltages across unfired resistors, significantly increasing the current and power demand. In the present invention, a three-terminal device, generally referred to as a transistor 24, permits multiple ejectors 10 to be attached to a matrix of row conductors 26 and column conductors 28 and eliminates power cross-talk in a matrix array of resistive elements. Row conductor 26 provides a digital logic signal to gate power supplied by column conductor 28. In this way, transistors 24 provide both power and logic multiplexing using either row conductor 26 or column conductor 28 to provide power to resistor 20 when a gating voltage is applied on the other conductor. Transistors 24 and individual ink feed slots 22 permit ejectors 10 to be organized on substrate 10 in large numbers of both columns and rows.

Transistor 24 can be fabricated in several ways. For example, when substrate 3 is a single crystalline semiconductor material such as silicon, transistor 24 can be included in substrate 3 by appropriately doping portions of the single crystalline semiconductor material forming substrate 3. Alternatively, transistor 24 can be arranged over substrate 3 and be formed by a plurality of thin film material layers over substrate 3.

FIG. 6 is a side sectional view of a transistor on a substrate in accordance with another embodiment of the invention. In the example, transistors 24 are thin-film transistors formed over dielectric layer 78 over substrate 3. Two doped areas 70 provide pools of charge in a semiconductor material, such as polysilicon. Channel 72 is disposed between doped areas 70 and is responsive to a field applied to gate electrode 74. The presence of a field on gate electrode 74 permits current to flow between doped areas 70. Various levels and types of n or p dopants can be applied to doped areas 70 and channel 72 to change the characteristics of transistor 24. Transistor contacts 76 are applied through dielectric 78 to supply power through transistor 24. In the invention, transistor contacts 76, for example, a first electrical contact and a second electrical contact, are formed of the material comprising row conductors 26 to minimize layers. In the case that substrate 3 is silicon, doped areas 70 and channel 72 are formed in the substrate through diffusion methods.

In the exemplary embodiment, gate electrode 74 and transistor contacts 76 are isolated areas of the material providing row conductor 26. An opening is made through dielectric layers 78 to provide substrate contact 80 between one transistor contact 76 and substrate 3. In the invention, two of the device terminals provide switching and power means, which are through gate electrode 74 and the transistor contact 76 not connected to substrate 3. The power return is through the substrate using substrate contact 80. In the invention, it is important that the substrate provide sufficient conductivity that the power delivered to multiple ejectors 10 be transmitted through substrate 3. In the case of very wide heads, the number of ejectors can be large, and applied power can be high. In the case that substrate 3 is silicon, the silicon must be heavily doped with either p or n type dopants to raise the conductivity of the wafer to a high level, below 1 ohm-centimeter, and preferably below 0.01 ohm-centimeter. Either n doping or p doping, with n dopants having the greates effect on reducing substrate resistance, can form doped silicon materials having such low resistance. In the case that substrate 3 is silicon and the substrate is highly conductive, row conductors 26 and column conductors 28 are isolated from the conductive substrate by dielectric 78. The embedded transistor 24 can also be isolated from the conductive silicon substrate 3 by the use of epitaxial layers as shown on page 306 of “Microchip Manufacturing”, by Stanley Wolf, ISBN 0-9616721-8-8. Conducting power back through the substrate eliminates additional layers and components. The structure permits row conductors 26 and column conductors 28 to be thin, and ejectors 10 can be packed closely together.

Column conductors 28 are formed over dielectric layer 78 and have through via to connect to isolated areas of conductor 26 that form a transistor contact 76 to complete the circuit. The structure of the matrix electrical backplane of the invention uses two metal layers spaced from substrate 3 by dielectric layer 78 and spaced from each other by a dielectric layer 78. The structure provides a logic and power matrix inkjet array backplane with a minimal number of layers.

In the case that substrate 3 is silicon, heavy n or p doping improves electrical conductivity. In the case of large matrix arrays of ejectors 10, the distance that power must travel through substrate 3 to the power supply connection can be on the order of several millimeters. If there are a large number of ejectors 10 on substrate 3, the power that transits substrate 3 can be high, causing a drop in voltage as power is transmitted through substrate 3. In that case, the resistance of the power traveling through substrate 3 can affect the performance of ejector 10. These problems can be overcome by improving the conductivity to the current flow from ejectors 10 to the power supply. These problems can occur in any material that comprises substrate 3 and has moderate conductivity.

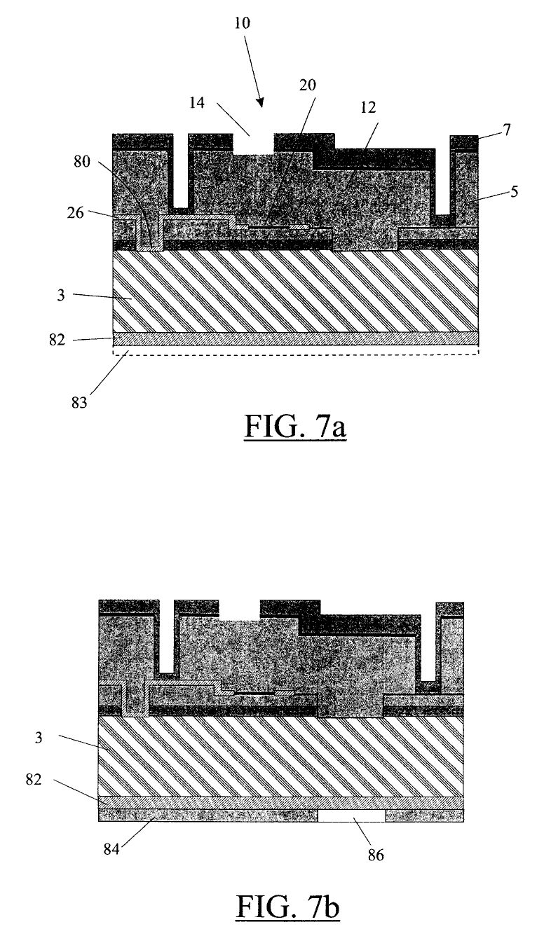

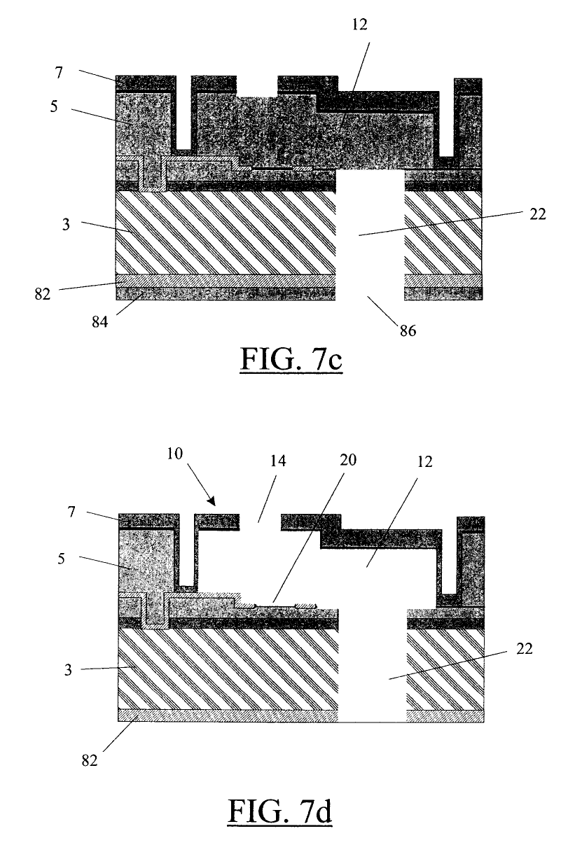

FIG. 7a is a side section view of an ejector on an inkjet head at a first step in the manufacturing process. Poor conductivity through substrate 3 is overcome in the invention by the application of a metallic backside conductor 82 on the backside of substrate 3. The deposited layer is preferably a highly conductive metal such as aluminum, copper, nickel, gold, or platinum. Backside conductor 82 is preferably formed of a metal which is unaffected by exposure to the fluid being ejected. One metal that can be used for backside conductor 82 is aluminum, which is inexpensive, can be deposited at great thickness and forms a native oxide layer that is impervious to most inks. A second material is nickel, which has less electrical conductivity and less resistance to corrosion from inks than aluminum. Nickel has the advantage of maintaining a low resistance surface after deposition that reduces resistance at the interface between conductive adhesive 33 and backside conductor 82.

Operations prior to FIG. 7a have formed ejector 10, one of many ejectors 10 which will form an inkjet head. A substrate contact 80 has been formed to provide a power conduit through substrate 3. The wafer first received a plasma etch to remove native silicon oxide from silicon substrate 3 and then aluminum was sputtered over the wafer to create aluminum substrate contact 80. These processes reduce the electrical resistance through substrate contact 80. An ejector structure has been formed over row conductor 26 using a polymer layer 5 and a cover layer 7. Polymer layer 5 is retained within ink chamber 12 until the end of processing.

In this first step of the process according to the invention, backside conductor 82 is formed by placing the assembly into a vacuum, plasma etching the backside of substrate 3 to remove the native silicon oxide and sputtering aluminum over the back of substrate 3 to form backside conductor 82. The aluminum layer can be, for instance 5 microns thick, which reduces resistance to power flow through the combination of substrate 3 and backside conductor 82. An additional conductor layer 83 of, for example, a precious metal such as gold, can be formed over backside conductor 82 to improve conductivity between backside conductor 82 and a connection to a power supply. In another embodiment, multiple metals are deposited simultaneously to optimize the sheet conductivity of backside conductor 82 and minimize contact resistance between backside conductor 82 and conductive adhesive 33.

FIG. 7b is a side section view of an ejector on an inkjet head at a second step in the manufacturing process. A backside mask 84 is formed over backside conductor 82. Backside mask 84 can be a polymer that is deposited directly over backside conductor 82. Backside mask 84 is photolithographically processed to create mask openings 86 through backside mask 84. Mask openings 86 are aligned to the positions that correspond to the desired location for ink feed slot 22.

FIG. 7c is a side section view of an ejector on an inkjet head at a third step in the manufacturing process. The wafer having ejector 10 is first etched to remove metal portions of backside conductor 82 exposed by contact openings 86. Etching processes are used to remove all layers comprising backside conductor 82 to expose silicon substrate 3. After removal of backside conductor 82, the wafer is placed in a deep reactive ion etching system and ink feed slot 22 is formed through silicon substrate 3 using a reactive ion etching process. The ion etching process is specific to silicon, and will not etch metals or polymers. Backside mask 84 can provide mask openings 86 for etching both backside conductor 82 and ink feed slot 22.

FIG. 7d is a side section view of an ejector on an inkjet head at a fourth step in the manufacturing process. The wafer having ejector 10 is placed in oxygen plasma and portions of polymer layer 5 that fill ink chamber 12 are removed. Backside mask 84 is removed to expose backside conductor 82. Removal of the polymer layer 5 which fills ink chamber 12 creates a fluidic circuit, which permits ink to pass through backside conductor 82 and substrate 3 to ink chamber 12. Applying appropriate power to resistor 20 forces ink out of ejector 10 through nozzle 14.

FIG. 8 is a schematic representation of an ejector array in accordance one example embodiment of the invention. A coordinate system is shown and includes a first direction X with X being an axis of motion between the printhead and an ink-receiving surface, commonly referred to as a printing direction. A second direction Y is also shown with Y being a cross printing direction. A direction Z is also shown with Z being a direction perpendicular to the printhead. This is commonly referred to as the direction of ink drop ejection from the printhead.

Ejectors 10 are shown schematically as a box having individual supply ports 22 and nozzles 14 and transistors 24. Ejectors 10 have been attached to a matrix of row conductors 26 and column conductors 28 to form laterally staggered columns of ejectors 10. Each ejector 10 of a column of ejectors is staggered at a desired pitch, typically expressed in dpi or microns, which is finer than the pitch of the ejector columns. For example, each column can be pitched 600 microns apart due to the area required for each ejector. If the required printing pitch is 40 microns, each ejector in the column can be laterally staggered 40 microns to a depth of 15 ejectors (40×15=600) to achieve the required 40 micron printing pitch. The invention permits the staggered matrix array to be placed on a single substrate. Transistors 24 attached to ejectors 10 use row conductors 26 as the gate lines and column conductors 28 as power supply lines to permit thermal drop-on-demand print heads having a large number of rows along printing direction X with close packing.

The embodiment shown in FIG. 8 is particularly well suited for print heads having large area arrays, for example, print heads having a print width across the Y direction of over of 100 millimeters and a print depth across the X dimension of at least 18 millimeters. However, the large area array print head can have other length and width dimensions. One head (or a plurality of large area array print heads stitched together) can be used to form a pagewide print head. In a pagewide print head, the length of the printhead is preferably at least equal to the width of the receiver and does not “scan” during printing. The length of the page wide printhead is scalable depending on the specific application contemplated and, as such, can range from less than one inch to lengths exceeding twenty inches.

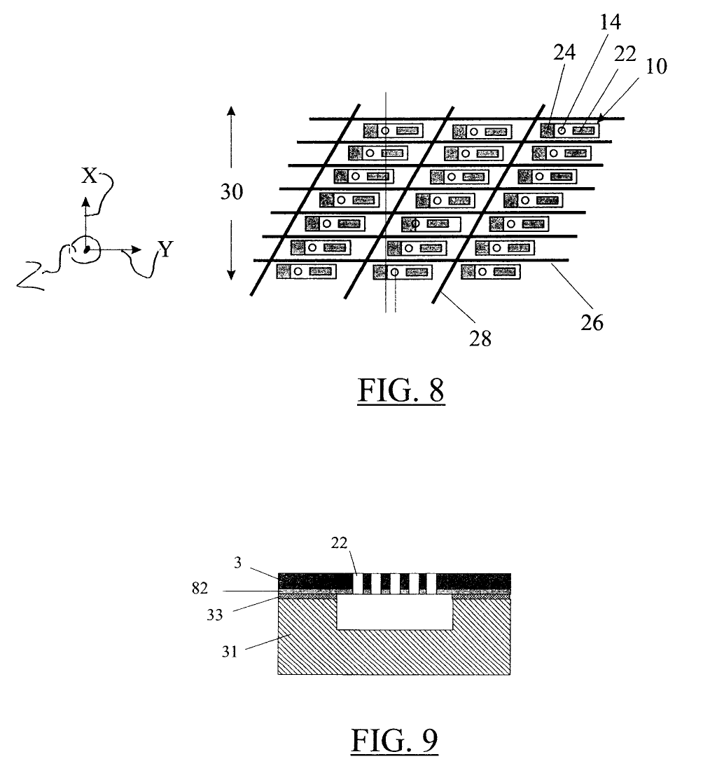

FIG. 9 is a side sectional view of an inkjet head in accordance with the invention. Ejectors 10 (not shown) are positioned in a large matrix array across substrate 3. Ink feed slots 22 pass through backside conductor 82 to supply fluid to ejectors 10. An electrically conductive head holder 31 transmits power through backside conductor 82 though a conductive adhesive 33 which secures print head 32 to head holder 31. The use of a precious metal as an overcoat prevents an oxide from covering backside conductor 82. The elimination of an oxide reduces possible resistance to power flow between conductive adhesive 33 and backside conductor 82. A metal or alloy having high electrical conductivity and low surface contact resistance can also be used in this application. In the large matrix array embodiment, the distance from centrally located ejectors is substantially greater than 1 millimeter, creating appreciable resistance to power flowing between the center of substrate 3 and electrically conductive adhesive 33. The addition of backside conductor 82 reduces resistance to power flow through the combination of substrate 3 and backside conductor 82.

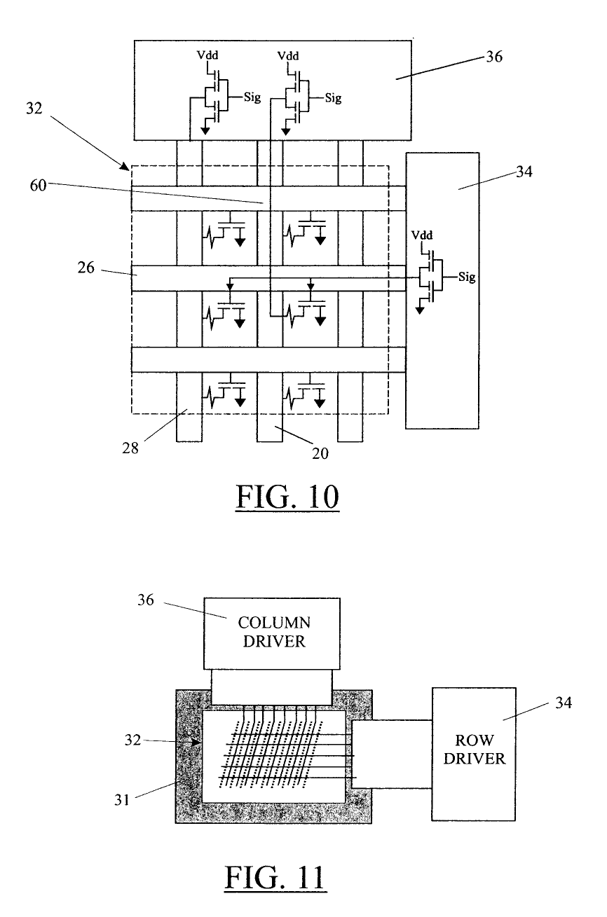

FIG. 10 is an electrical schematic of an inkjet head in accordance with the present invention. Print head 32 includes a plurality of drivers electrically connected to the plurality of row conductors and the plurality of column conductors. The plurality of drivers is operable to provide current to each resistive element row sequentially. Each column conductor 28 is connected to a column driver 36. Column driver 36 can be, for example, an ST Microelectronics STV 7612 Plasma Display Panel Diver chip that is connected to each column conductor 28. The chip responds to digital signals to either apply a drive voltage or ground to each column conductors. Each row conductor 26 is connected to a row driver 34. Row driver 34 can be the same ST Microelectronics STV 7612 Plasma Display Panel Diver chip to provide either a gating voltage (Vdd) or ground to each row conductor 26. Transistor 24, provided with each ejector 10, responds to the logic and power states to permit print head 32 to be logically driven in a row sequential fashion without parasitic resistance effects.

Print head 32 is fired row sequentially. Digital signals apply a drive voltage (Vdd) or ground voltage to each column conductor 28. Column conductors 28 having an applied drive voltage provide energy to the ejector attached to column conductor 28 and the grounded row conductor 26. Column conductors 28 at ground voltage are not fired. Row driver 34 applies a Gate voltage (Vdd) to a row of ejectors 10 to enable firing of powered ejectors 10 of a given row, while the remaining rows remain at ground voltage regardless of power applied to their associated column conductor 28. This process is repeated to apply an image wise pattern of ink droplets from print head 32.

Only a single ejector 10 on any given column conductor 28 is active at any one time, which permits column conductor 28 to be thin. However, all ejectors 10 on the selected row conductor 26 can be fired, which represents a large amount of current and power that must be returned through substrate 3. In a head having thirty activated heater resistors 20 on a line, each sinking 50 milli-amperes, 1.5 amps will pass through substrate 3. Power from each ejector 10 must pass through contact 80, substrate 3 and through conductive adhesive 33 in the case that power is transmitted through head holder 31. The addition of backside conductor 82 reduces resistance to power flow. The edges of substrate 3 can provide a large amount of surface area to transmit the power, in particular wide print heads will have large contact areas that will scale with width.

FIG. 11 is a schematic view of a head assembly in accordance with the present invention. Print head 32 has been mounted to head holder 31, which holds a supply of ink in a cavity behind substrate 3 to supply ink through substrate 3 to ejectors 10 mounted on the front of substrate 3. Row driver 34 and column driver 36 are attached to head holder 31 and wire bonds are made between the flex circuit for the drivers to the row and column conductors on print head 32. The width of the head is not limited to a single column driver 36. The width can be extended and additional column drivers 36 added to provide power to additional columns.

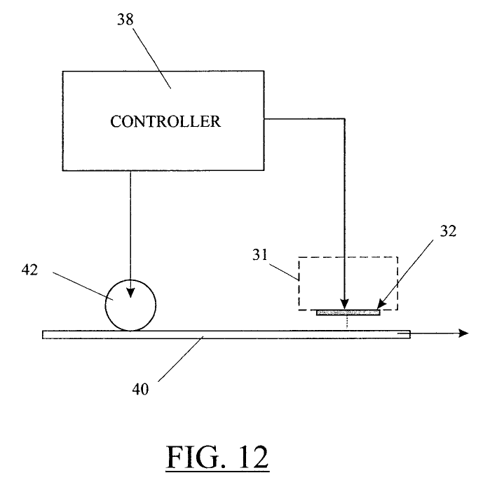

FIG. 12 is a schematic side view of a printer using a head in accordance with the present invention. Controller 38 moves an ink receiver 40 using receiver driver 42. Receiver driver 42 is a motor that operates on a plate or roller to drive ink receiver 40 under print head 32. Controller 38 provides drive signals to row driver 34 and column driver 36 connected to print head 32 to apply an image-wise pattern of ink droplets onto ink receiver 40 in synchronization with the motion of ink receiver 40.

The invention has been described in detail with particular reference to certain preferred embodiments thereof, but it will be understood that variations and modifications can be effected within the scope of the invention.

### PARTS LIST

3 substrate
5 polymer layer
7 cover
10 ejector
12 ink chamber
14 nozzle
16 inlet
18 restriction
20 heater resistor
22 ink feed slot
24 transistor
26 row conductor
28 column conductor
30 spacing distance
31 head holder
32 print head
33 conductive adhesive
34 row drivers
36 column drivers
38 printer controller
40 ink receiver
42 receiver driver
52 ejector drivers
54 conductor lines
58 control logic
60 bond pads
62 wire bonds
64 flex circuit
70 doped areas
72 channel
74 gate electrode
76 transistor contacts
78 dielectric layer
80 substrate contact
82 backside conductor
83 additional conductor layer
84 backside mask
86 mask openings

What is claimed is:

1. A print head comprising:
a substrate including a first side and a second side;
an ejector located on the first side of the substrate, the ejector including a fluid chamber, portions of the fluid chamber defining a nozzle bore, and a resistive element operable to eject fluid present in the fluid chamber through the nozzle bore of the fluid chamber, the resistive element being electrically connected to the substrate;
a conductor located on the second side of the substrate, the conductor being electrically connected to the substrate; and
a supply passage through the conductor and the substrate, the supply passage being in fluid communication with the fluid chamber of the ejector to supply a fluid to the fluid chamber.

2. The print head of claim 1, wherein the substrate is silicon.

3. The print head of claim 3, wherein the silicon is doped to permit sufficient current to flow through the substrate to actuate the ejector.

4. The print head of claim 1, further comprising:
a head holder operable to secure the print head; and
an electrically conductive adhesive positioned to provide a physical attachment and an electrical connection between the conductive layer and the head holder.

5. The print head of claim 1, the ejector being one of a plurality of ejectors located on the first side of the substrate.

6. The print head of claim 5, wherein the plurality of ejectors are arranged on the first side of the substrate in rows and columns.

7. The print head of claim 6, wherein the plurality of ejectors are arranged on the first side of the substrate in rows and columns in a staggered array.

8. The print head of claim 1, wherein the conductor is a metal layer.

9. The print head of claim 8, wherein the metal layer is aluminum.

10. The print head of claim 1, the conductor being a first conductor, further comprising:
a second conductor arranged on the first side of the substrate to supply power to the resistive element, the second conductor being electrically connected to the resistive element and the substrate.

11. A method of forming a print head comprising:
providing a substrate including a first side and a second side;
providing an ejector located on the first side of the substrate, the ejector including a fluid chamber, portions of the fluid chamber defining a nozzle bore, and a resistive element operable to eject fluid present in the fluid chamber through the nozzle bore of the fluid chamber, the resistive element being electrically connected to the substrate;
providing a conductor located on the second side of the substrate, the conductor being electrically connected to the substrate;
providing a mask over the conductor; and
forming a supply passage through the conductor and the substrate by:
removing a portion of the conductor not covered by the mask; and
removing a portion of the substrate not covered by the mask.

12. The method of claim 11, wherein providing the mask over the conductor includes forming a polymer layer over the conductor.

13. The method of claim 12, wherein removing the portion of the conductor not covered by the mask includes using a wet etching process to remove the portion of the conductor not covered by the mask.

14. The method of claim 13, the substrate being a silicon substrate, wherein removing the portion of the substrate not covered by the mask includes using a reactive ion etching process to remove the portion of the substrate not covered by the conductor.

15. The method of claim 11, further comprising:
removing the mask after formation of the supply passage is complete.

16. The method of claim 15, wherein providing the ejector located on the first side of the substrate includes forming the fluid chamber of the ejector using a material removal process after formation of the supply passage.

17. The method of claim 16, further comprising:
removing the mask, wherein removing the mask occurs simultaneously with formation of the fluid chamber.

18. The method of claim 11, the conductor being a first conductor, the method further comprising:
providing a second conductor arranged on the first side of the substrate to supply power to the resistive element, the conductor being electrically connected to the resistive element and the substrate.
